(19) United States
(12) Patent Application Publication
(10) Pub. No.: US 2025/0211178 A1
(43) Pub. Date: Jun. 26, 2025

(54) AMPLIFIER CIRCUIT

(71) Applicant: Silicon Integrated Systems Corp., Hsinchu City (TW)

(72) Inventors: Wen-Chi LIN, Hsinchu City (TW); Ssu-Che YANG, Hsinchu City (TW); Keng-Nan CHEN, Hsinchu City (TW)

(73) Assignee: Silicon Integrated Systems Corp., Hsinchu City (TW)

(21) Appl. No.: 18/955,036

(22) Filed: Nov. 21, 2024

(30) Foreign Application Priority Data
Dec. 22, 2023 (TW) 112150201

(51) Int. Cl. H03F 1/32

(52) U.S. Cl. CPC H03F 1/3211; H03F 2200/144; H03F 2200/21

(57) ABSTRACT

An amplifier circuit includes a programmable-gain amplifier, a first resistor, a second resistor and at least one third resistor. The programmable-gain amplifier has a first positive input terminal, a first negative input terminal, a second positive input terminal, a second negative input terminal, a positive output terminal and a negative output terminal. The first resistor is connected between the first negative input terminal and the positive output terminal. One terminal of the second resistor is connected to the first negative input terminal and the first resistor, and another terminal is connected to the second positive input terminal. The at least one third resistor is connected between the second positive input terminal and the negative output terminal. A sum of resistances of each of the first resistor and the second resistor is the same as a resistance of the at least one third resistor.

### CROSS-REFERENCE TO RELATED APPLICATIONS

This non-provisional application claims priority under 35 U.S.C. § 119(a) on Patent Application No(s). 112150201 filed in Republic of China (ROC) on Dec. 22, 2023, the entire contents of which are hereby incorporated by reference.

### BACKGROUND

### 1. Technical Field

This disclosure relates to an amplifier circuit, especially to an amplifier circuit capable of addressing the issue of output signal distortion without additional single-terminal to double-terminal circuit.

### 2. Related Art

Under the differential difference amplifier (DDA) architecture, as the amplitude of the input signal increases, the resistive feedback may easily cause the linearity of the output signal to deteriorate dramatically, causing distortion in subsequent signal processing. Therefore, if the differential difference amplifier architecture is operated under large signal amplitude conditions, it may be only suitable for double-terminal input and not suitable for circuit applications of converting single-terminal input into double-terminal output.

### SUMMARY

Accordingly, this disclosure provides an amplifier circuit which is capable of addressing the issue of output signal distortion without additional single-terminal to double-terminal circuit.

According to one or more embodiment of this disclosure, an amplifier circuit includes a programmable-gain amplifier, a first resistor, a second resistor and at least one third resistor. The programmable-gain amplifier has a first positive input terminal, a first negative input terminal, a second positive input terminal, a second negative input terminal, a positive output terminal and a negative output terminal. The first resistor is connected between the first negative input terminal and the positive output terminal. One terminal of the second resistor is connected to the first negative input terminal and the first resistor, and another terminal is connected to the second positive input terminal. The at least one third resistor is connected between the second positive input terminal and the negative output terminal. The sum of the resistances of the first resistor and the second resistor is the same as the resistance of the at least one third resistor.

In view of the above description, the amplifier circuit of the present disclosure, by specially designing the impedance between specific terminals of the programmable-gain amplifier, may form a non-inverting amplifier structure at the first positive input terminal and the first negative input terminal of the programmable-gain amplifier, and form an inverting amplifier structure at the second positive input terminal and the second negative input terminal of the programmable-gain amplifier. Regarding the selection of the resistance of the resistor, the sum of the resistances of the first resistor connected between the first negative input terminal and the positive output terminal, and the second resistor connected to the first negative input terminal and the first resistor is used as a reference, and the resistance of the at least one third resistor connected between the second positive input terminal and the negative output terminal is the same as the reference. In this way, an effect of overcoming signal distortion even when the amplitude of the single-terminal input signal is large may be achieved, and there is no need to set up additional single-terminal to double-terminal circuit.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a circuit diagram of an amplifier circuit according to an embodiment of the present disclosure;

FIG. 2 is a circuit diagram of an amplifier circuit according to another embodiment of the present disclosure; and

FIG. 3 is a signal diagram of an amplifier circuit according to an embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

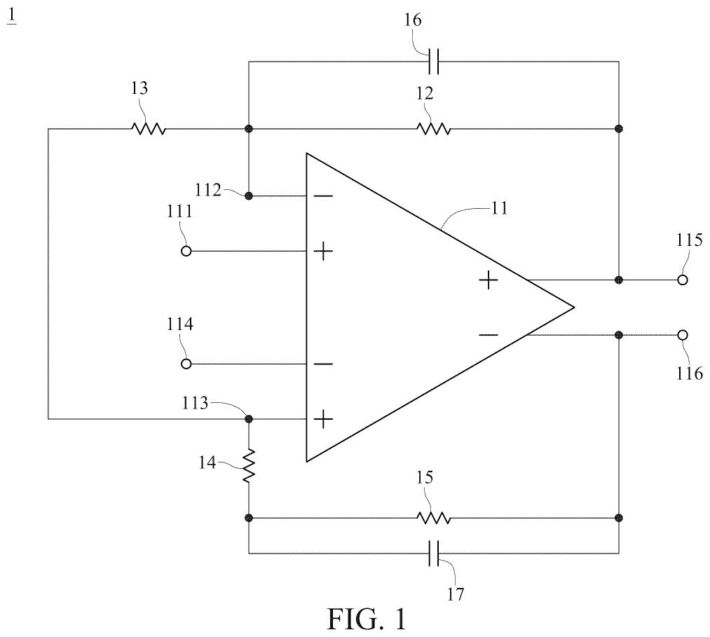

Please refer to FIG. 1 which is a circuit diagram of an amplifier circuit according to an embodiment of the present disclosure. As shown in FIG. 1, an amplifier circuit 1 includes a programmable-gain amplifier 11, a first resistor 12, a second resistor 13, two third resistors 14 and 15, a first capacitor 16 and a second capacitor 17. The programmable-gain amplifier 11 has a first positive input terminal 111, a first negative input terminal 112, a second positive input terminal 113, a second negative input terminal 114, a positive output terminal 115 and a negative output terminal 116. The first resistor 12 is connected between the first negative input terminal 112 and the positive output terminal 115. One terminal of the second resistor 13 is connected to the first negative input terminal 112 and the first resistor 12, and another terminal is connected to the second positive input terminal 113. The third resistor 14 is connected between the second positive input terminal 113 and the third resistor 15. The third resistor 15 is connected between the third resistor 14 and the negative output terminal 116. The first resistor 12 and the third resistor 15 have the same resistance. The second resistor 13 and the third resistor 14 have the same resistance. It should be noted that the first capacitor 16 and the second capacitor 17 of the amplifier circuit 1 are optionally disposed.

In the present embodiment, the programmable-gain amplifier (PGA) 11 is an amplifier that allows the user to adjust the gain and has a high input impedance, and has four input terminals and two output terminals (double-terminal output). Specifically, the programmable-gain amplifier 11 may include two operational amplifiers. The positive input terminal of the first operational amplifier may correspond to the first positive input terminal 111, and the negative input terminal of the first operational amplifier may correspond to the first negative input terminal 112. The positive input terminal of the second operational amplifier may correspond to the second positive input terminal 113, and the negative input terminal of the second operational amplifier may correspond to the second negative input terminal 114. The output terminal of the first operational amplifier may correspond to the positive output terminal 115, and the output terminal of the second operational amplifier may correspond to the negative output terminal 116. However, the above merely serves as an example, and the present disclosure is not limited thereto.

The amplifier circuit can be designed with different functions through various connection of the terminals of the programmable-gain amplifier 11. As shown in FIG. 1, in the present embodiment, the first negative input terminal 112 of the amplifier circuit 1 is connected to the positive output terminal 115, and the first positive input terminal 111 receives an input signal, so this first operational amplifier may be referred to as a noninverting amplifier. The second positive input terminal 113 of the amplifier circuit 1 is connected to the negative output terminal 116, and the second negative input terminal 114 receives another input signal, so this second operational amplifier may be referred to as an inverting amplifier.

In the present embodiment, the first resistor 12 is connected between the first negative input terminal 112 and the positive output terminal 115, one terminal of the second resistor 13 is connected to the first negative input terminal 112 and another terminal of the second resistor 13 is connected to the second positive input terminal 113, and the third resistors 14 and 15 are connected in series with each other and connected between the second positive input terminal 113 and the negative output terminal 116. The first resistor 12 and the third resistor 15 have the same resistance Rf. In addition, the second resistor 13 and the third resistor 14 in the present embodiment may have the same resistance Rs. Through this configuration, the gain of the amplifier circuit 1 of the present embodiment may be expressed by the following relational expression, wherein G is the gain.
Relational expression: G=(Rs+Rf)/Rs

Furthermore, the selection of the resistance may also be related to the noise and power consumption designed for the amplifier circuit 1. For example, the smaller the resistance, the lower the circuit noise may be (thermal noise is 4 kTR, wherein k is Boltzmann's constant, T is temperature, and R is resistance), and the power consumption is greater (P=V²/R, wherein P is power consumption, V is voltage, R is resistance); in opposite, the greater the resistance, the greater the circuit noise may be and the smaller the power consumption is lower. In addition to the resistor, the amplifier circuit 1 of the present embodiment may further include a first capacitor 16 and a second capacitor 17. One terminal of the first capacitor 16 is connected to the positive output terminal 115 and another terminal of the first capacitor 16 is connected to the first negative input terminal 112. One terminal of the second capacitor 17 is connected to the negative output terminal 116, and another terminal of the second capacitor 17 is connected between the third resistor 14 and the third resistor 15, wherein the first capacitor 16 and the second capacitor 17 have the same capacitance. Through the first capacitor 16 and the second capacitor 17, high-frequency noise may be filtered, further improving the quality of signal processing. It should be noted that the first capacitor 16 and the second capacitor 17 may also be provided selectively. The capacitor in the present embodiment serves as a low-pass filter and may filter high-frequency noise beyond the signal frequency band of the signal input to the first positive input terminal 111 by selecting a specific capacitance. Moreover, if the signal input to the first positive input terminal 111 is an extremely high frequency signal, the capacitor may not be necessary.

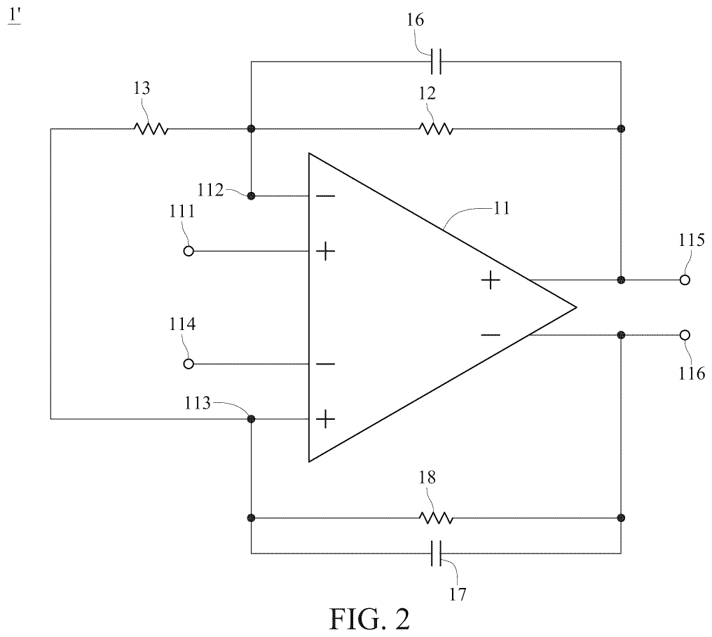

Please refer to FIG. 2 which is a circuit diagram of an amplifier circuit according to another embodiment of the present disclosure. As shown in FIG. 2, in the present embodiment, the programmable-gain amplifier 11 (including a first positive input terminal 111, a first negative input terminal 112, a second positive input terminal 113, a second negative input terminal 114, a positive output terminal 115 and a negative output terminal 116), the first resistor 12, the second resistor 13, the first capacitor 16 and the second capacitor 17 of the amplifier circuit 1′, and the connection therebetween may be the same as that of embodiment in FIG. 1. In comparison, the second capacitor 17 in the present embodiment may be directly connected between the second positive input terminal 113 and the negative output terminal 116, and the third resistor 18 is directly connected between the second positive input terminal 113 and the negative output terminal 116 and may correspond to the third resistors 14 and 15 of the embodiment of FIG. 1. In other words, the second capacitor 17 and the third resistor 18 in the present embodiment are connected in parallel with each other and connected between the second positive input terminal 113 and the negative output terminal 116. The resistance of the third resistor 18 is the sum of the resistances of the third resistors 14 and 15 in previous embodiment, that is, the resistance of the third resistor 18 is equivalent to the sum of the resistances of the first resistor 12 and the second resistor 13. In addition, in some embodiments, the third resistor 18 may be formed by multiple resistors connected in series.

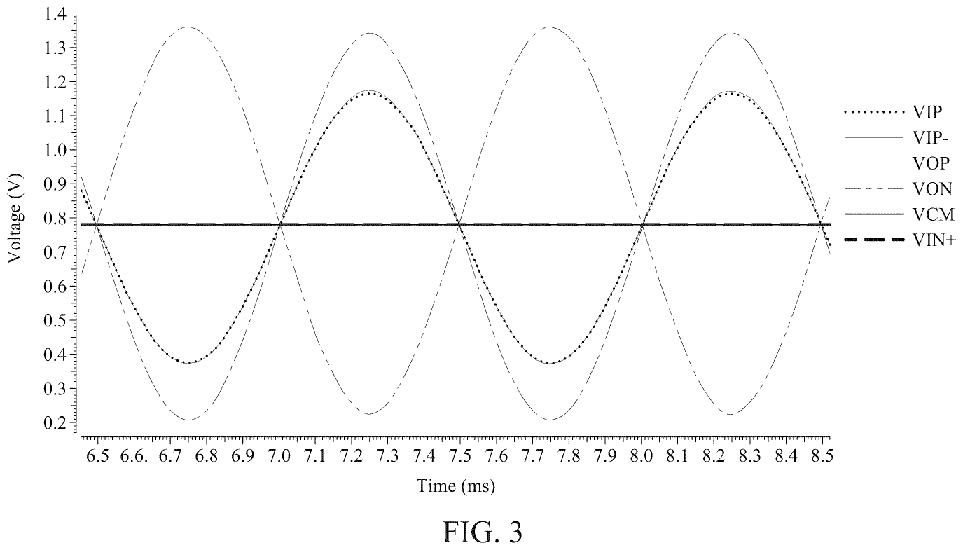

In application, the first positive input terminal 111 of the amplifier circuits 1 and 1′ may be configured to receive an AC input signal (VIP), and the second negative input terminal 114 may be configured to receive a DC signal (VCM). Please refer to FIG. 3 along with FIG. 1 or FIG. 2, FIG. 3 is a signal diagram of an amplifier circuit according to an embodiment of the present disclosure. FIG. 3 schematically shows the waveform of the AC input signal VIP received by the first positive input terminal 111, the waveform of the AC feedback signal VIP− transmitted by the first negative input terminal 112, the waveform of the common mode signal VCM received by the second negative input terminal 114, the waveform of the common mode feedback signal VIN+ transmitted by the second positive input terminal 113, the waveform of the forward output signal VOP output by the positive output terminal 115, and the waveform of the reverse output signal VON output by the negative output terminal 116. As shown in FIG. 3, for example, the amplitude of the AC input signal VIP input from the first positive input terminal 111 is approximately 1.1 to 1.2 volts (V), and the period is approximately 1 millisecond (ms). In comparison, the common mode signal VCM input from the second negative input terminal 114 is a DC signal, and its level is approximately 0.8 volts (V). Therefore, the amplifier circuit 1 in the present embodiment adopts the single-terminal input signal mode.

When the first positive input terminal 111 and the second negative input terminal 114 respectively receive the AC input signal VIP and the common mode signal VCM, the programmable-gain amplifier 11 may generate the AC feedback signal VIP− at the first negative input terminal 112 and the common-mode feedback signal VIN+ at the second positive input terminal 113 through the above components and circuit connections. Specifically, the AC feedback signal VIP− has the same phase and similar amplitude as the AC input signal VIP, and the common-mode feedback signal VIN+ and the common-mode signal VCM have the same voltage level.

Furthermore, the programmable-gain amplifier 11 may generate the forward output signal VOP at the positive output terminal 115 through the above components and circuit connections, and generate the reverse output signal VON at the negative output terminal 116. The forward output signal VOP and the AC input signal VIP have the same phase. The forward output signal VOP and the reverse output signal VON have opposite polarities (a phase difference of 180 degrees) and have the same amplitude. Specifically, the amplitudes of the forward output signal VOP and the reverse output signal VON are determined by the gain described above. In this embodiment, the amplitudes of the forward output signal VOP and the reverse output signal VON are approximately 1.3 to 1.4 volts (V).

The amplifier circuits 1 and 1′ described above may be particularly applied to single-ended input applications that require analog-to-digital conversion, such as microphones, touch panels, etc.

In view of the above description, the amplifier circuit of the present disclosure, by specially designing the impedance between specific terminals of the programmable-gain amplifier, may form a non-inverting amplifier structure at the first positive input terminal and the first negative input terminal of the programmable-gain amplifier, and form an inverting amplifier structure at the second positive input terminal and the second negative input terminal of the programmable-gain amplifier. Regarding selection of the resistance of the resistor, the sum of the resistances of the first resistor connected between the first negative input terminal and the positive output terminal, and the second resistor connected to the first negative input terminal and the first resistor is used as a reference, and the resistance of the at least one third resistor connected between the second positive input terminal and the negative output terminal is the same as the reference. In this way, an effect of overcoming signal distortion even when the amplitude of the single-terminal input signal is large may be achieved, and there is no need to set up additional single-terminal to double-terminal circuit. In addition, by applying filter capacitors in the non-inverting amplifier and inverting amplifier described above respectively, high-frequency noise may be filtered and the quality of signal processing may be further improved.

What is claimed is:

1. An amplifier circuit, comprising:
a programmable-gain amplifier having a first positive input terminal, a first negative input terminal, a second positive input terminal, a second negative input terminal, a positive output terminal and a negative output terminal;
a first resistor connected between the first negative input terminal and the positive output terminal;
a second resistor having one terminal connected to the first negative input terminal and the first resistor, and another terminal connected to the second positive input terminal; and
at least one third resistor connected between the second positive input terminal and the negative output terminal,
wherein a sum of resistances of the first resistor and the second resistor is same as a resistance of the at least one third resistor.

2. The amplifier circuit of claim 1, wherein the first positive input terminal is configured to receive an AC signal, and the second negative input terminal is configured to receive a DC signal.

3. The amplifier circuit of claim 1, wherein a number of the at least one third resistor is two, one terminal of a first one of the at least one third resistor is connected to the second positive input terminal, and one terminal of a second one of the at least one third resistor is connected to the negative output terminal.

4. The amplifier circuit of claim 3, wherein the first one of the at least one third resistor and the second resistor have a same resistance, and the second one of the at least one third resistor and the first resistor have a same resistance.

5. The amplifier circuit of claim 1, further comprising a first capacitor, wherein one terminal of the first capacitor is connected to the positive output terminal and another terminal of the first capacitor is connected to the first negative input terminal.

6. The amplifier circuit of claim 3, further comprising a second capacitor, wherein one terminal of the second capacitor is connected to the negative output terminal and another terminal of the second capacitor is connected between the first one and the second one of the at least one third resistor.

7. The amplifier circuit of claim 1, further comprising a second capacitor, wherein one terminal of the second capacitor is connected to the negative output terminal and another terminal of the second capacitor is connected to the second positive input terminal.

8. The amplifier circuit of claim 3, further comprising a first capacitor and a second capacitor, wherein one terminal of the first capacitor is connected to the positive output terminal, another terminal of the first capacitor is connected to the first negative input terminal, one terminal of the second capacitor is connected to the negative output terminal, and another terminal of the second capacitor is connected between the first one and the second one of the at least one third resistor.

9. The amplifier circuit of claim 1, further comprising a first capacitor and a second capacitor, wherein one terminal of the first capacitor is connected to the positive output terminal, another terminal of the first capacitor is connected to the first negative input terminal, one terminal of the second capacitor is connected to the negative output terminal, and another terminal of the second capacitor is connected to the second positive input terminal.

10. The amplifier circuit of claim 8, wherein the first capacitor and the second capacitor have a same capacitance.

11. The amplifier circuit of claim 9, wherein the first capacitor and the second capacitor have a same capacitance.
